(19) United States
(12) Patent Application Publication
(10) Pub. No.: US 2014/0353469 A1
(43) Pub. Date: Dec. 4, 2014

(54) IMAGE SENSOR, SEMICONDUCTOR DEVICE AND IMAGE SENSOR SYSTEM

(71) Applicant: SK hynix Inc., Gyeonggi-do (KR)

(72) Inventors: Do-Hyung KIM, Gyeonggi-do (KR); Jang-Won MOON, Gyeonggi-do (KR); Youn-Sub LIM, Gyeonggi-do (KR); Do-Hwan KIM, Gyeonggi-do (KR)

(73) Assignee: SK hynix Inc., Gyeonggi-do (KR)

(21) Appl. No.: 14/056,617

(22) Filed: Oct. 17, 2013

(30) Foreign Application Priority Data
Jun. 3, 2013 (KR) 10-2013-0063296

(51) Int. Cl. H01L 27/146; H04N 5/378

(52) U.S. Cl. CPC H01L 27/1463; H04N 5/378
USPC 250/208.1; 257/461

(57) ABSTRACT

The present technology provides a semiconductor device that includes a substrate including an active region and an device isolation region, a plurality of micro insulation structures formed in the substrate of the device isolation region and spaced from each other, and an impurity region suitable for filling spaces between the micro insulation structures and for surrounding the micro insulation structures in the substrate of the device isolation region, and a method of fabricating the semiconductor device by improving a method of forming device isolation regions that insulate active regions. In particular, discontinuous micro insulation structures are suggested.

### CROSS-REFERENCE TO RELATED APPLICATIONS

The present application claims priority of Korean Patent. Application No. 10-2013-0063296, filed on Jun., 03 2013, which is incorporated herein by reference in its entirety.

### BACKGROUND

1. Field

Exemplary embodiments of the present invention relate to an image sensor, a semiconductor device for device isolation, and an image sensor system.

2. Description of the Related Art

With rapid progress of high speed and high integration of semiconductor devices, demands for miniaturization of patterns and high accuracy of pattern dimensions have increased. The same also applies to device isolation layers occupying a relatively large region as well as patterns formed in active regions.

In most present semiconductor devices, the device isolation layers are formed using a Shallow Trench Isolation (STI) process to ensure the sizes of active regions and realize high-integrated devices.

FIGS. 1 to 3 are diagrams illustrating a device isolation configuration of a complementary meta oxide semiconductor (CMOS) image sensor according to the related art.

Referring to FIG. 1, an insulation structure 12 is formed in a semiconductor substrate 10. The insulation structure 12 may be formed by an STI process, may have a continuous configuration to surround a photodiode 11, and may isolate the photodiode 11 from other photodiodes (not shown).

The STI process is performed by anisotropically etching the semiconductor substrate 10 to form a trench (not shown), and then filing the trench with an insulation layer (not shown) to form the insulation structure 12. At this time, many dangling bonds existing in an interface between the trench and the insulation structure 12 cause dark current. The dark current becomes a noise signal generated when there is no light in the image sensor. The dark current may deteriorate characteristics of the image sensor in which an optical image is converted into an electric signal.

In order to resolve the above-mentioned concern, a barrier layer (44a in FIG. 3) is formed between the interface between the trench and the insulation structure 12 by implanting impurity ions into an exposed surface inside the trench after forming the trench to prevent the dark current from occurring and thus enhancing device isolation characteristics.

FIG. 2 is a plan view illustrating a process of implanting the impurity ions into the exposed surface inside the trench after the trench is formed. FIG. 3 is a plan view illustrating a case in which an annealing process is performed on an impurity region 44 in FIG. 2.

Referring to FIG. 2, the impurity region 44 is formed by implanting the impurity ions into the exposed surface inside the trench. Referring to FIG. 3, a diffused impurity region 44a is formed by the annealing process on the impurity region 44 to diffuse the impurity ions in the impurity region 44.

The impurity ions in the impurity region 44 are diffused to the photodiode 11 to form the diffused impurity region 44a. As a result, an area of the photodiode 11 becomes reduced due to the impurity ions diffused to the photodiode 11, thereby resulting in deterioration in image realization characteristics of the CMOS image sensor.

In detail, diffusion of the impurity ions is unavoidably caused by the annealing process. The impurity ions diffuse into the photodiode 11 and an occupation region of the impurity ions is expanded, so the diffused impurity region 44a is formed. As the occupation region of the impurity ions increases, the region of the photodiode 11 conversely decreases. As a result, the area of the photodiode 11, which receives light, decreases, and, thus, the image realization characteristics of the CMOS image sensor may deteriorate.

### SUMMARY

Various exemplary embodiments are directed to an image sensor, where a loss of a photodiode area is minimized while a dark current source is removed, and a method of fabricating the image sensor. Also, various exemplary embodiments are directed to a semiconductor device, which is capable of realizing excellent insulation characteristics and micro device isolation, and a method of fabricating the semiconductor device.

In an exemplary embodiment, a semiconductor device may include a substrate, including an active region and an device isolation region, a plurality of micro insulation structures formed in the substrate of the device isolation region and spaced from each other, and an impurity region suitable for filling spaces between the micro insulation structures and surrounding the micro insulation structures in the substrate of the device isolation region.

In an exemplary embodiment, a method of fabricating a semiconductor device may include forming a plurality of trenches spaced from each other in a substrate, forming a plurality of micro insulation structures by filling the trenches with an insulating material, and forming an impurity region filling spaces between the micro insulation structures and surrounding the micro insulation structures.

In an exemplary embodiment, an image sensor may include a substrate including an active region and an device isolation region, a photodiode formed in the substrate of the active region, a plurality of micro insulation structures formed in the substrate of the device isolation region and spaced from each other, and an impurity region suitable for filling spaces between the micro insulation structures and surrounding the micro insulation structures in the substrate of the device isolation region.

### BRIEF DESCRIPTION OF THE DRAWINGS

FIG. 1 is a perspective view illustrating a device isolation configuration of a CMOS image sensor according to the related art.

FIG. 2 is a plan view illustrating a process of implanting impurity ions into a substrate inside a trench.

FIG. 3 is a plan view illustrating a case in which an annealing process is performed on an impurity region in FIG. 2.

FIG. 4 is a perspective view illustrating a device isolation configuration of a CMOS image sensor according to an exemplary embodiment.

FIG. 5 is a plan view illustrating a case in which a process of implanting impurities into an insulation structure in FIG. 4 is performed.

FIG. 6 is a plan view illustrating a case in which thermal treatment process is performed on an impurity region in FIG. 5.

FIG. 7 is a sectional view taken along the line A-A′ of FIG. 6.

FIG. 8 is a block diagram illustrating a configuration of an image sensor according to an exemplary embodiment of the present invention.

FIG. 9 is a block diagram illustrating a system including an image sensor according to the exemplary embodiment of the present invention.

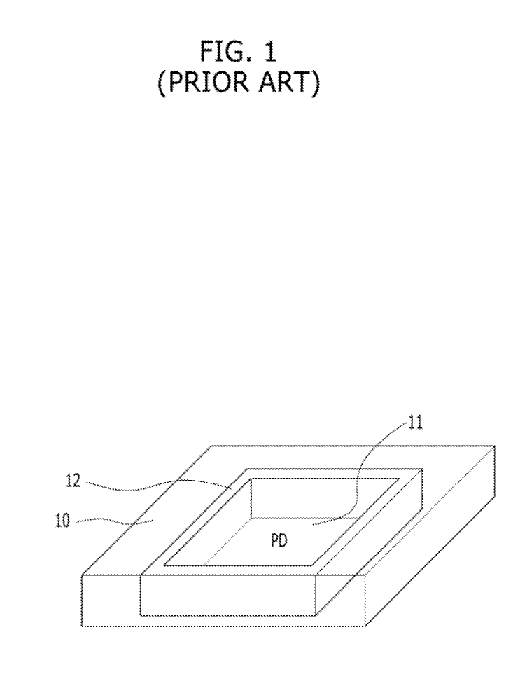

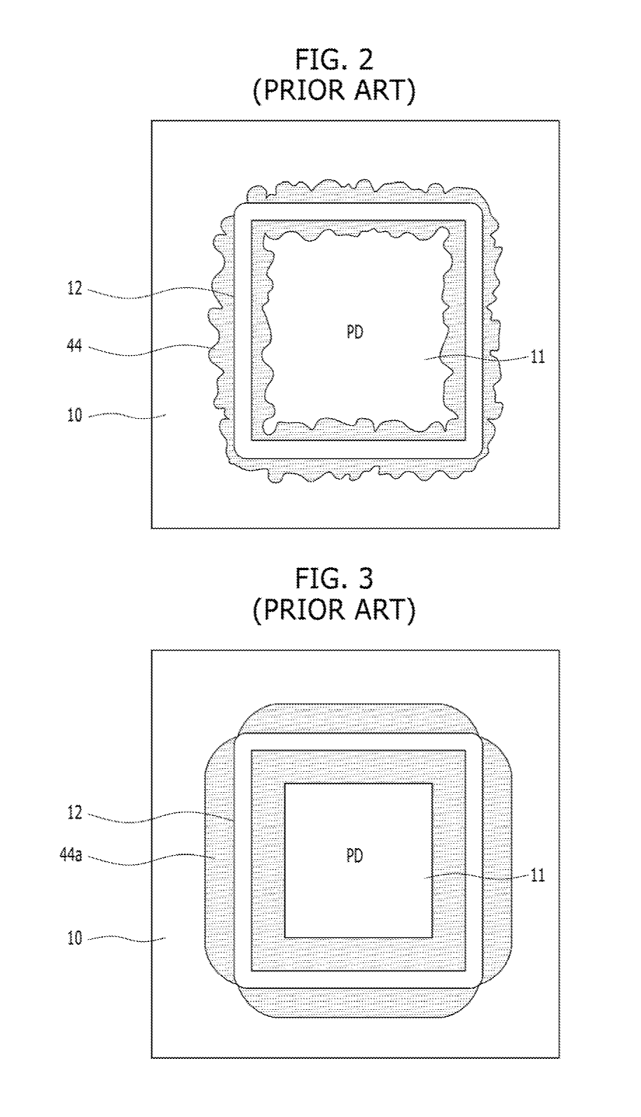

### DETAILED DESCRIPTION

Various exemplary embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, reference numerals correspond directly to the like numbered parts in the various figures and embodiments of the present invention.

In the description of embodiments, when layers (or layer), regions, pattern, or structures are referred to as being formed “on or “under” layers (layer), regions, pads or patterns, all of the cases in which the layers (layer), the regions, the pattern, and the structures are formed directly and indirectly “on” or “under” are included.

Further, a reference for “on” or “under” is referred to the drawings. In the drawings, the thickness or size of each layer is exaggerated, omitted, or schematically illustrated to facilitate the description and to achieve accuracy.

Hereinafter, preferred exemplary embodiments will be described with reference to the appended drawings to make the description in detail so that those skilled in the art may easily embody the technical sprit.

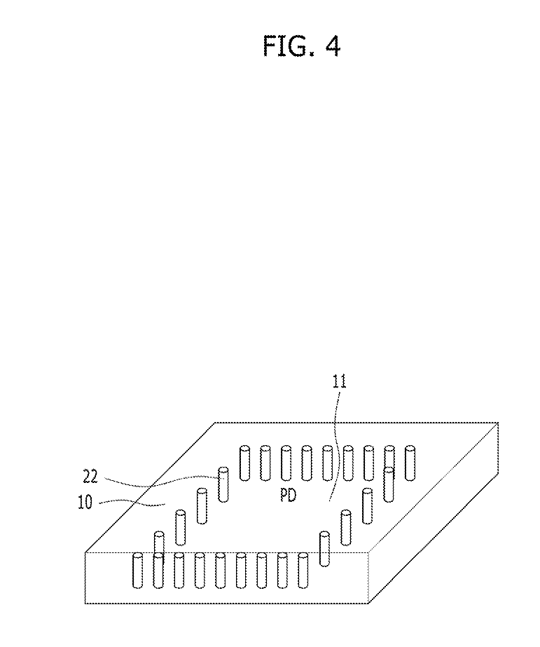

FIGS. 4 to 6 are perspective and plan views illustrating a CMOS image sensor having a substrate including a plurality of micro insulation structures 22 according to an exemplary embodiment.

Referring to FIGS. 4 to 6, the CMOS image sensor, according to the exemplary embodiment device, may include the plurality of micro insulation structures 22 spaced from each other. A diffused impurity region 55a is formed to fill spaces between the micro insulation structures 22 and to surround the micro insulation structures 22.

In detail, referring to FIG. 4, the plurality of micro insulation structures 22 may be formed in a discontinuous pillar type and may be disposed around a photodiode 11 to be spaced from each other. The micro insulation structure 22 may be a local oxidation of silicon (LOCOS) formed by oxidizing silicon, which is a material of a semiconductor substrate 10, or may be a Shallow Trench Isolation (STI) formed by embedding an insulation layer such as an oxide layer in a trench. Preferably, the micro insulation structures 22 may be formed with an STI with excellent device isolation characteristics in a high integrated circuit.

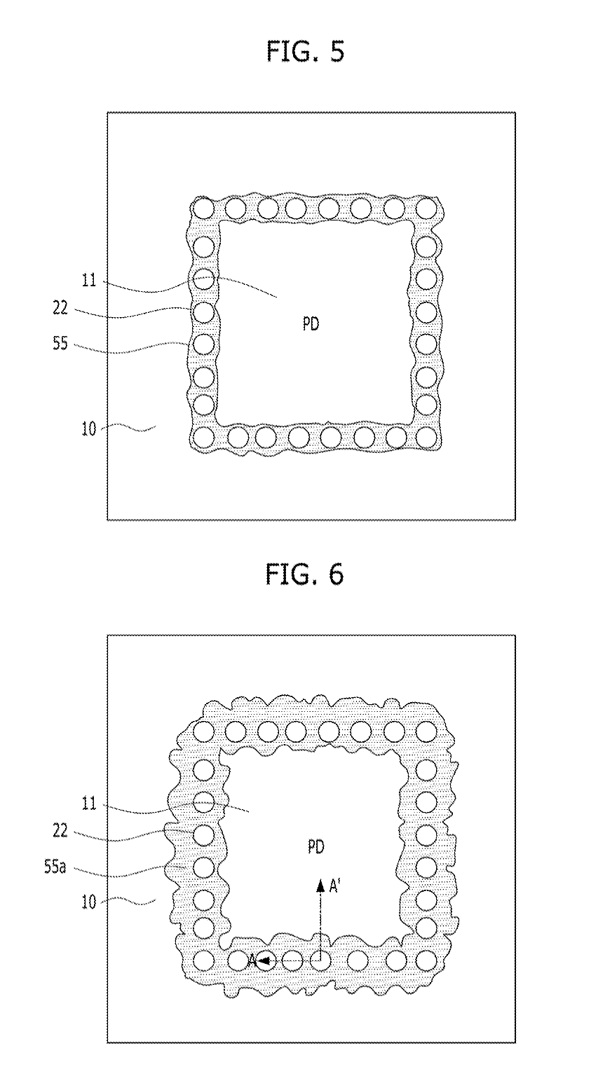

Referring to FIGS. 5 and 6, the diffused impurity region 55a is formed to fill the spaces of the adjacent micro insulation structures 22 and to surround the micro insulation structures 22.

In detail, referring to FIG. 5, an impurity region 55 is formed by performing an ion implanting process into the semiconductor substrate 10 near the micro insulation structures 22. Referring to FIG. 6, the diffused impurity region 55a is formed by performing a thermal treatment process on the impurity region 55 to diffuse impurities in the impurity region 55. The diffused impurity region 55a is formed to fill the spaces between the micro insulation structures 22 and to surround the micro insulation structures 22 by the thermal treatment process. At this time, the impurities may be N-type or P-type impurities. In the exemplary embodiment, the P-type impurities are preferably implanted. Accordingly, the diffused impurity region 55a and the micro insulation structures 22 form a structure, which surrounds the photodiode 11 and isolates the photodiode 11 from other photodiodes (not shown). The thermal treatment process may include an annealing process.

In the exemplary embodiment, in comparison to the related art, it may be understood that a larger area of the photodiode 11 may be ensured due to the micro insulation structures 22 spaced from each other when the thermal treatment process is performed on the impurities in the forms of the insulation structure 12 of the related art and the micro insulation structures 22 of the exemplary embodiment.

A method of fabricating the CMOS image sensor, according to the exemplary embodiment, will be described with reference to FIGS. 5 to 7.

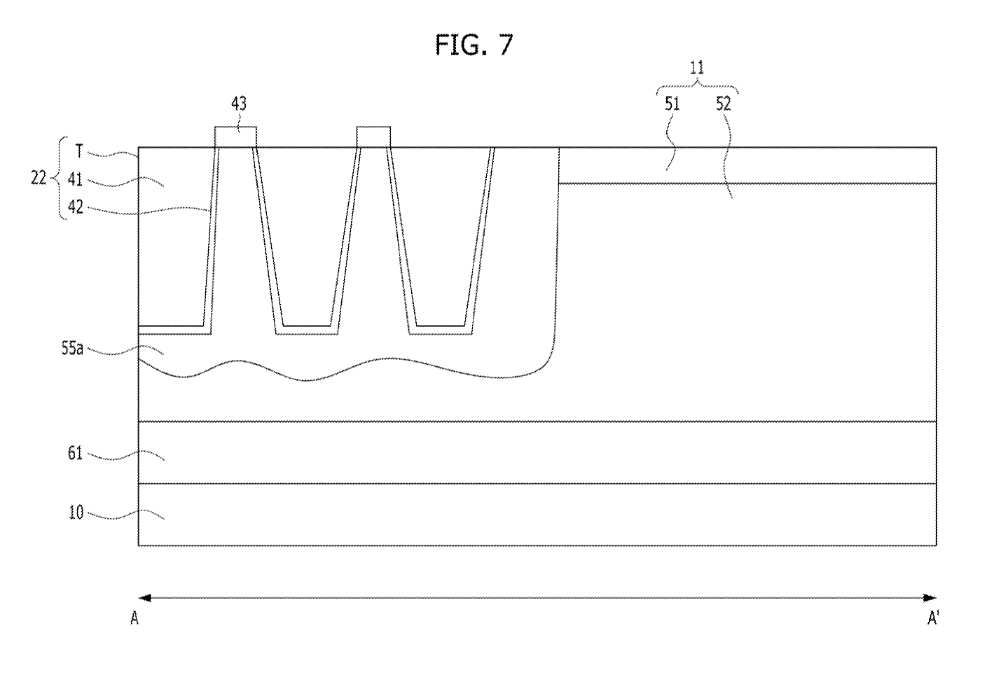

FIG. 7 is a sectional view taken along the like A-A of FIG. 6 and illustrates a device isolation structure formed by embedding the impurities into the plurality of micro insulation structures 22 and performing the thermal treatment process.

The forming of the micro insulation structures 22 may include forming a plurality of trenches T by anisotropically etching the semiconductor substrate 10 using trench mask patterns 43 as etching masks after forming the trench mask patterns 43 having a circular-type opening portion over the semiconductor substrate 10.

In the related art, the insulation structure 12 formed by the STI process has a continuous form. In the exemplary embodiment, the trench mask patterns 43 are preferably formed to have the circular-type opening portion so that the micro insulation structures 22 may be formed in a discontinuous form such as the pillar type. The trench mask pattern 43 may have a dual structure of a silicon oxide layer (SiO₂) and a silicon nitride layer (Si₃N₄).

Accordingly, the plurality of trenches T having the discontinuous form serves to define the photodiode 11. After the plurality of trenches T spaced from each other are formed in the semiconductor substrate 10 device isolation layers 41 are formed by filling the trenches T. Thereafter, the mask patterns 43 may be removed.

According to the exemplary embodiment, a thermal oxidation process may be further performed to form silicon oxide layers 42 over inner walls of the trenches T after forming the trenches T. Etching damage occurring in the anisotropic etching process to form the trenches T may be recovered due to the thermal oxidation process. Since the etching damage on sidewalls of the trenches T may cause the dark current, the thermal oxidation process may contribute to an improvement in the image realization characteristics of the image sensor.

The device isolation layers 41 are formed to have a thickness to sufficiently fill the trenches T. At this time, empty spaces, that is, voids, may be preferably not formed in the device isolation layers 41 in the trenches T. Here, though there is a slight difference, according to the design rule of the semiconductor device, the device isolation layers 41 may be stacked by an O₃-Tetra-Ethyl-Ortho-Silicate (O₃-TEOS) Atmosphere Pressure Chemical Vapor Deposition (AP CVD) process or a High Density Plasma Chemical Vapor Deposition (HDP CVD) process.

On the other hand, the device isolation layers 41 may be formed as a plurality of layers, that is, two or more layers of an oxide layer or a nitride layer.

When the STI process is used, a process of etching the trenches T is necessarily performed. At this time, crystal defects may exist in boundary portions of the trenches T in many cases. The crystal defects may be accumulated during the process of forming the device isolation layers 41 or may occur in subsequent processes. Since the crystal defects serves as traps capturing electrons, the crystal defects act as defects or noise components of pixels, thereby increasing the dark current.

However, according to the exemplary embodiment, the ion implanting process is performed into the semiconductor substrate 10 near the minute insulation structures 22 to form the impurity region 55 so that the dark current is prevented from occurring. By the ion implanting process, side and bottom surfaces of the trenches T act as protective layers. FIG. 5 is a plan view illustrating a case in which the ion implanting process is performed into the semiconductor substrate 10 near the micro insulation structures 22 of FIG. 4. In FIG. 5, the impurity region 55 is formed to fill the spaces between the micro insulation structures 22 and to surround the micro insulation structures 22.

In summary, the impurity region 55 is formed to fill the spaces between the micro insulation structures 22 and to surround the micro insulation structures 22 by performing the ion implantation process into the semiconductor substrate 10 near the micro insulation structures 22 using the trench mask patterns 43 as a barrier layer. As a result, the impurity region 55 may be formed in the bottom and side surfaces of the trenches T.

After the ion implantation process is performed, the implanted impurities are diffused through the thermal treatment process. During this process, the impurities diffuse, that is, the impurities diffuse in the spaces between the discontinuously formed micro insulation structures 22 with the pillar type so that the diffused impurity region 55a is formed to fill the spaces between the micro insulation structures 22 and to surround the micro insulation structures 22. As the impurities diffuse in the spaces in which the micro insulation structures 22 are spaced, the amount of impurity diffusing inside the photodiode 11 may be reduced.

When the thermal treatment process is performed, defects, such as dangling bond, humidity, or the like, may be removed. That is, the diffused impurity region 55a and the micro insulation structures 22 may form a device isolation structure, which surrounds the photodiode 11 and isolates the photodiode 11 from other photodiodes (not shown) so as to minimize the effect of the dark current.

In the thermal treatment process, the diffused impurity region 55a may be formed by performing a Rapid Thermal process (RTP). Accordingly, the impurities may be diffused with a uniform density to be formed.

The impurities of the impurity region 55 may be controlled to have a conductive type according to a conductive type of the substrate corresponding to an active region (not shown). Preferably, the insulation characteristics of the micro insulation structures 22 may be intensified by forming the impurities to have a conductive type opposite to the active region. The description will be made with reference to FIG. 7. FIG. 7 is the sectional view taken along the line A-A′ of FIG. 6. FIG. 7 illustrates a device isolation structure of the micro insulation structures 22 and the diffused impurity region 55a surrounding the photodiode 11.

The photodiode 11 may have a junction configuration of an upper P-type impurity region 51 and a lower N-type impurity region 52. The lower N-type impurity region 52 is joined to a deep P-type well 61 below the lower N-type impurity region 52. The P-type impurity may be, for example, boron (B) or BF₂. The N-type impurity may be, for example, arsenic (As) or phosphorus (P). Accordingly, in view of the cross-section, the photodiode 11 has a PN junction diode configuration. The photodiode 11 and the deep P-type well 61 have a PNP junction diode configuration. In this case, the semiconductor substrate 10 may be doped with N-type or P-type impurities. The semiconductor substrate 10 may preferably be doped with the N-type impurities, and the diffused impurity region 55a may preferably be doped with the P-type impurities.

Eventually, the diffused impurity region 55a forms a diode junction with two adjacent photodiodes 11 to insulate the adjacent photodiodes 11 from each other. That is, the diffused impurity region 55a doped with the P-type impurities forms an NPN diode junction along with the lower N-type impurity regions 52 of the two adjacent photodiodes 11. The NPN diode junction may maintain a reverse bias condition, and thus the two adjacent photodiodes 11 may be insulated electrically from each other.

When the insulation structure 12 and the diffused impurity region 44a in FIG. 3 are compared to the micro insulation structures 22 and the diffused impurity region 55a, the diffused impurity region 44a diffusing to the area of the photodiode 11 of the related art forms an excessive diffusion region in the side and bottom surfaces of the insulation structure 12, but it may be confirmed that the diffused impurity region 55a of the exemplary embodiment diffuse to the spaces between the micro insulation structures 22 with the pillar type.

That is, since the diffused impurity region 55a does not invade the area of the photodiode 11, the area of the photodiode 11 capable of receiving light is not reduced. Therefore, it is possible to improve the image realization characteristics of the CMOS image sensor.

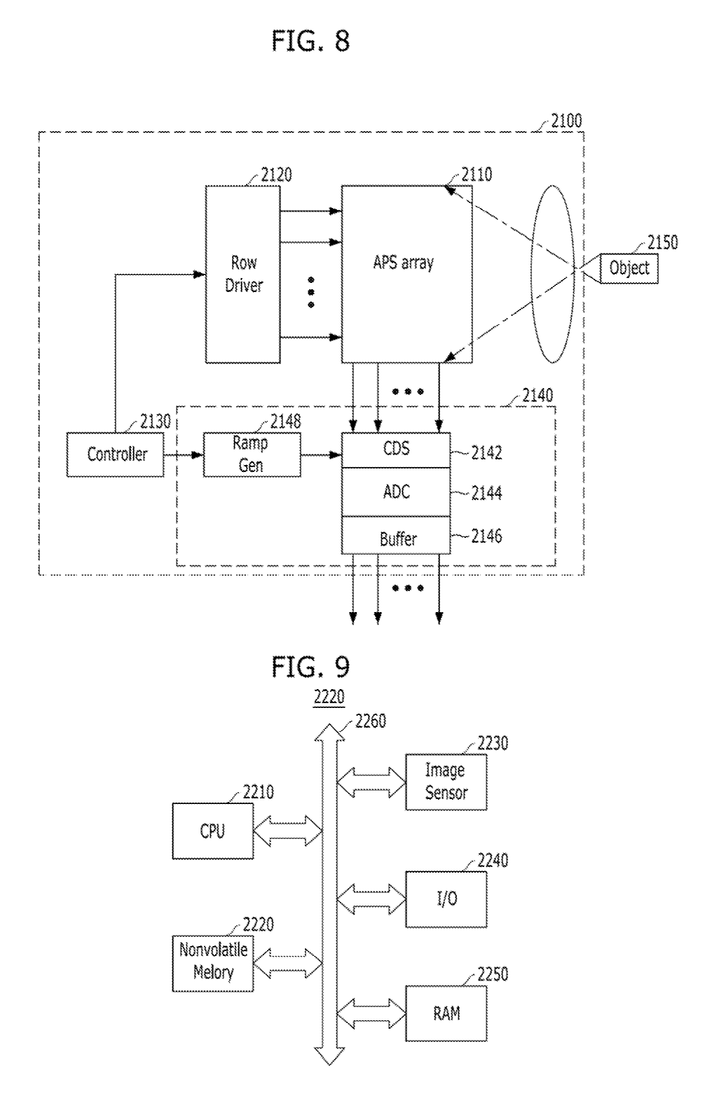

FIG. 8 is a block diagram illustrating a configuration of an image sensor according to an exemplary embodiment of the present invention.

As illustrated in FIG. 8, a CMOS image sensor 2100 may include an active pixel sensor array (APS array) 2110, a controller 2130, a row driver 2120, and a pixel signal processor 2140. The active pixel sensor array 2110 may include the image sensor according to the exemplary embodiment of the present invention. Specifically, the active pixel sensor array 2110 may include a plurality of micro insulation structures formed in a substrate of a device isolation region, the substrate including an active region and the device isolation region spaced from each other, and an impurity region configured to fill spaces between the micro insulation structures 22 and to surround the micro insulation structures 22 inside the substrate of the device isolation region.

The active pixel sensor array 2110 outputs electrical pixel signals corresponding to incident light by converting the electrical pixel signals in a plurality of photodiodes. The electrical pixel signals are provided to the pixel signal processor 2140 through vertical signal lines. Pixel sensors in the active pixel sensor array 2110 are read out one by one once in units of rows. Accordingly, all of the pixels in one row of the active pixel sensor array 2110 are simultaneously activated by a row selection signal, which is an output of the row driver 2120.

Each pixel in the selected row provides a signal corresponding to incident light to an output line of a corresponding column. In the active pixel sensor (APS) array 2110, each column includes a selection line, and the pixels in each column are selectively read out in response to a column selection signal. The rows in the active pixel sensor (APS) array 2110 are activated in response to an output signal of the row driver 2120.

The controller 2130 controls the row driver 2120 and the pixel signal processor 2140 to perform a process suitable for a pixel signal output from the active pixel sensor array 2110. The pixel signal processor 2140 includes a correlated double sampler (CDS) 2142, an analog-digital converter (ADC) 2144, and a buffer 2146.

The correlated double sampler (CDS) 2142 receives the electrical pixel signals generated in the active pixel sensor array 2110 via the vertical signal line and then samples and holds the electrical pixel signals. That is, the correlated double sampler 2142 doubly samples a specified noise level and a signal level of the generated electrical pixel signals and outputs a difference level corresponding to a difference between the noise level and the signal level. Ramp signal values generated from a ramp signal generator (Ramp Gen) 2148 may be input and compared to each other, and then the comparison result may be output to an output end. The ramp signal generator (Ramp Gen) 2148 may operate based on a control signal generated from the controller 2130.

The analog-digital converter (ADC) 2144 converts an analog signal corresponding to the difference level into a digital signal. The buffer 2146 includes a column memory block (not illustrated) and a sense amplifier (not illustrated). The column memory block (not illustrated) may include a plurality of memories (not illustrated).

The buffer 2146 latches the digital signal. The latched signal is output sequentially to an image processor (not illustrated) according to a decoding result of a column decoder (not illustrated).

The CMOS image sensor 2100 in FIG. 8 may be realized as one semiconductor chip by further including an image processor (not illustrated). The image processor (not illustrated) performs appropriate image processing on digitized pixel signals and outputs image data. The CMOS image sensor 2100 senses an object imaged by a lens under the control of the image processor (not illustrated). The image processor (not illustrated) may output an image sensed and may output by the image sensor 2100 to a display unit (not illustrated). At this time, the display unit (not illustrated) includes all of the devices capable of outputting a video. For example, the display unit (not illustrated) may include a computer, a cellular phone, and other video output terminals. The CMOS image sensor 2100 illustrated in FIG. 8, according to the exemplary embodiment of the present invention, may include the mage sensor according to the exemplary embodiment of the present invention. Accordingly, an area loss of the active region may be minimized and image data undamaged by dark current may be output.

FIG. 9 is a block diagram illustrating a system including an image sensor according to an exemplary embodiment of the present invention.

Here, a system 2200 in FIG. 9 may be a computer system, a camera system, a scanner, a car navigation system, a video phone, a security system, and a motion detection system in which image data is necessary.

As illustrated in FIG. 9, the system 2200 includes a central processing unit (CPU) 2210 or a processor 2210, a non-volatile memory 2220, an image sensor 2230, an input/output (I/O) device 2240, and a random access memory (RAM) 2250.

The central processing unit (CPU) 2210 communicates with the input/output (I/O) device 2240 via a bus 2260.

The image sensor 2230 communicates with the central processing unit (CPU) 2210 via the bus 2260. The RAM 2250 and the non-volatile memory 2220 also communicate with the central processing unit (CPU) 2210 via the bus 2260. The image sensor 2230 may be present as an independent semiconductor chip or may be coupled with the central processing unit 2210 to form one semiconductor chip.

The image sensor 2230 included in the system in FIG. 9 may include the image sensor according to the exemplary embodiment of the present invention. The image sensor 2230 includes the image sensor including the micro insulation structures 22 illustrated in FIG. 6. Accordingly, an area loss of the active region may be minimized, and image data undamaged by dark current may be output.

The improved semiconductor device, according to the exemplary embodiment, includes a plurality of trenches and micro insulation layers spaced from each other in the device isolation region of the substrate. Accordingly, impurities diffuse to the portions in which the micro insulation layers are spaced from each other, and thus the diffusion to the adjacent active region is further reduced compared to the related art. Accordingly, an area loss of the active region may be minimized. When the device isolation configuration is applied to the CMOS image sensor, the area of the photodiode may be sufficiently ensured, and thus optical sensitivity characteristics of the image sensor may be considerably improved.

Although various embodiments have been described for illustrative purposes, it will be apparent to those skilled in the art that various changes and modifications may be made without departing from the spirit and scope of the invention as defined in the following claims.

What is claimed is:

1. A semiconductor device comprising:
a substrate including an active region and an device isolation region;
a plurality of micro insulation structures formed in the substrate of the device isolation region and spaced from each other; and
an impurity region suitable for filling spaces between the micro insulation structures and for surrounding the micro insulation structures in the substrate of the device isolation region.

2. The semiconductor device of claim 1, wherein the plurality of micro insulation structures include an insulating material for filling of trenches formed in the substrate of the device isolation region.

3. The semiconductor device of claim 1, wherein the plurality of micro insulation structures have a pillar type.

4. The semiconductor device of claim 1, wherein the impurity region surrounds side and bottom surfaces of the plurality of micro insulation structures.

5. The semiconductor device of claim 1, wherein the impurity region has an N or P conductive type according to a conductive type of the substrate of the active region.

6. The semiconductor device of claim 1, further comprising:
a photodiode formed in the active region.

7. The semiconductor device of claim 2, further comprising:
an oxide layer formed over an interface between the trench and the micro insulation structures.

8. The semiconductor device of claim 7, wherein the oxide layer includes silicon oxide.

9. An image sensor comprising:
a substrate including an active region and an device isolation region;
a photodiode formed in the substrate of the active region;
a plurality of micro insulation structures formed in the substrate of the device isolation region and spaced from each other; and
an impurity region suitable for filling spaces between the micro insulation structures and surrounding the micro insulation structures in the substrate of the device isolation region.

10. The image sensor of claim 9, wherein the plurality of micro insulation structures have a pillar type.

11. The image sensor of claim 9, wherein the impurity region surrounds side and bottom surfaces of the plurality of micro insulation structures.

12. The image sensor of claim 9, wherein the impurity region has an N or P conductive type according to a conductive type of the substrate of the active region.

13. An image sensor system comprising:
an active pixel sensor array comprising an image sensor suitable for outputting electrical pixel signals corresponding to incident light by converting the electrical pixel signals in a plurality of photodiodes;
a row driver suitable for activation the row of the active pixel sensor array;
pixel signal processor suitable for performing a process suitable for a pixel signal output from the active pixel sensor array;
a pixel signal processor suitable for receiving the electrical pixel signals from the image sensor; and
a controller suitable for controlling the row driver and the pixel signal processor 2140 to perform a process suitable for a pixel signal output from the active pixel sensor array.

14. The image sensor system of claim 13, wherein image sensor system, comprising:
a plurality of micro insulation structures formed in a substrate including an active region and the device isolation region spaced from each other;
an impurity region suitable for filling spaces between the micro insulation structures and surrounding the micro insulation structures inside the substrate of the device isolation region.

15. The image sensor system sensor of claim 14, wherein the plurality of micro insulation structures include an insulating material for filling of trenches formed in the substrate of the device isolation region.

16. The image sensor system of claim 14, wherein the plurality of micro insulation structures have a pillar type.

17. The image sensor system of claim 14, wherein the impurity region surrounds side and bottom surfaces of the plurality of micro insulation structures.

18. The image sensor system of claim 14, wherein the impurity region has an N or P conductive type according to a conductive type of the substrate of the active region.

19. The image sensor system of claim 14, further comprising:
a photodiode formed in the active region.
